(19) United States
(12) Patent Application Publication
(10) Pub. No.: US 2002/0185121 A1
(43) Pub. Date: Dec. 12, 2002

(54) Group encapsulated dicing chuck

(76) Inventors: Warren M. Farnworth, Nampa, ID (US); Tom A. Muntifering, Boise, ID (US)

Correspondence Address: TRASK BRITT, P.O. BOX 2550, SALT LAKE CITY, UT, 84110, US

(21) Appl. No.: 09/875,063

(22) Filed: Jun. 6, 2001

(51) Int. Cl. B26D 3/00; B28D 1/32; H01L 21/328

(52) U.S. Cl. 125/23.01; 125/13.01; 83/35; 83/43; 83/474; 83/884

(57) ABSTRACT

A semiconductor wafer saw and method of using the same for dicing semiconductor wafers are disclosed comprising a wafer saw including variable lateral indexing capabilities and multiple blades. The wafer saw, because of its variable indexing capabilities, can dice wafers having a plurality of differently sized semiconductor devices thereon into their respective discrete components. In addition, the wafer saw with its multiple blades, some of which may be independently laterally or vertically movable relative to other blades, can more efficiently dice silicon wafers into individual semiconductor devices.

### BACKGROUND OF THE INVENTION

1. Field of the Invention

This invention relates generally to a method and apparatus for dicing or sawing semiconductor substrates having encapsulated semiconductor devices thereon, and more specifically to a saw and chuck and method of using the same employing using multiple indexing techniques and multiple blades for more efficient sawing from an array of semiconductor devices on a substrate.

2. State of the Art

An individual integrated circuit semiconductor device, semiconductor die, or chip is usually formed from a larger structure known as a semiconductor wafer, which is usually comprised primarily of silicon, although other materials such as gallium arsenide and indium phosphide are also sometimes used. Each semiconductor wafer has a plurality of integrated circuits arranged in rows and columns with the periphery of each integrated circuit being rectangular. Typically the wafer is sawn or “diced” into rectangularly shaped discrete integrated circuits along two mutually perpendicular sets of parallel lines or streets lying between each of the rows and columns thereof. Hence, the separated or singulated integrated circuits are commonly referred to as dice.

One exemplary wafer saw includes a rotating dicing blade mounted to an aluminum hub and attached to a rotating spindle, the spindle being connected to a motor. Cutting action of the blade may be effected by diamond particles bonded thereto, or a traditional “toothed” type blade may be employed. Many rotating wafer saw blade structures are known in the art. The present invention is applicable to any saw blade construction so further structures will not be described herein.

Because semiconductor wafers in the art usually contain a plurality of substantially identical integrated circuits arranged in rows and columns, two sets of mutually parallel streets extending perpendicular to each other over substantially the entire surface of the wafer are formed between each discrete integrated circuit and are sized to allow passage of a wafer saw blade between adjacent integrated circuits without affecting any of their internal circuitry. Prior to the sawing of a semiconductor wafer to singulate the wafer and to create individual semiconductor die from the wafer, a piece of tape, typically referred to as wafer tape, is applied to the back side of the wafer so that once the wafer has been singulated, the individual semiconductor die remain attached to the wafer tape for further handling and processing.

Once the wafer tape has been applied to the back side of the wafer, a typical wafer sawing operation includes attaching the semiconductor wafer to a wafer saw carrier, mechanically, adhesively or otherwise as known in the art and mounting the wafer saw carrier on the table of the wafer saw. A blade of the wafer saw is passed through the surface of the semiconductor wafer, either by moving the blade relative to the wafer, the table of the saw and the wafer relative to a stationary blade, or a combination of both. To dice the wafer, the blade cuts precisely along each street, returning back over (but not in contact with) the wafer while the wafer is laterally indexed to the next cutting location. Once all cuts associated with mutually parallel streets having one orientation are complete, either the blade is rotated 90° relative to the wafer or the wafer is rotated 90°, and cuts are made through streets in a direction perpendicular to the initial direction of cut. Since each integrated circuit on a conventional wafer has the same size and rectangular configuration, each pass of the wafer saw blade is incrementally indexed one unit (a unit being equal to the distance from one street to the next) in a particular orientation of the wafer. As such, the wafer saw and the software controlling it are designed to provide uniform and precise indexing in fixed increments across the surface of a wafer.

Once the individual or singulated semiconductor die have been sawed, the semiconductor die are further processed being removed from the wafer tape, attached to substrates and packaged, such as the semiconductor die being adhesively attached to a substrate in a board-over-chip configuration (BOC), connections made between the semiconductor die and the circuits of the substrate by wire bonding, and the semiconductor die and portions of the substrate being encapsulated. While the semiconductor die and substrate may be individually handled, it is more efficient to process a plurality of semiconductor die, each semiconductor die being individually mounted, on a substrate having a configuration providing for each individually mounted semiconductor die thereon and circuits for connection with each individually semiconductor die as well as for the encapsulation of each individual semiconductor die mounted on the substrate.

However, existing process equipment and apparatus does not have the capability of singulating the packaged semiconductor die on a substrate when a plurality of semiconductor die are contained in an array on a substrate.

### SUMMARY OF THE INVENTION

Accordingly, an apparatus and method for sawing semiconductor substrates, including substrates having a plurality of semiconductor devices of different sizes and/or shapes therein, is provided. In particular, the present invention provides a saw and method of using the same capable of “multiple indexing” a saw blade or blades to provide the desired cutting capabilities. As used herein, the term “multiple indexing” contemplates and encompasses both the lateral indexing of a saw blade at multiples of a fixed interval and at varying intervals which may not comprise exact multiples of one another. Thus, for conventional substrate and/or wafer configurations containing a number of equally sized integrated circuits, the wafer saw and method herein can substantially simultaneously saw the substrates and/or wafers with multiple blades and therefore cut more quickly than single blade wafer saws known in the art. Moreover, for wafers having a plurality of differently-sized or -shaped integrated circuits, the apparatus and method herein provides a multiple indexing capability to cut non-uniform dice from the same wafer.

The present invention includes a substrate chuck mounted on a table used in conjunction with the saw for holding a substrate having an array of encapsulated semiconductor devices mounted thereon for singulation. The chuck comprises a chuck table, at least one cutting pedestal, at least one clamp, at least one clamp pedestal, and an alignment apparatus for aligning a substrate for singulation in the chuck. The alignment apparatus may comprise at least one alignment pin having a portion thereof attached to the chuck table and having a portion engaging the substrate to be singulated or a recess in the chuck table for receiving the substrate to be singulated therein.

In one embodiment, a single-blade, multi-indexing saw is provided for cutting a substrate containing variously configured semiconductor devices thereon which may be encapsulated. By providing multiple-indexing capabilities, the saw can sever the wafer into differently sized mounted encapsulated semiconductor devices corresponding to the configuration of the semiconductor devices contained thereon.

In another embodiment, a saw is provided having at least two wafer saw blades spaced a lateral distance from one another and having their centers of rotation in substantial parallel mutual alignment. The blades are preferably spaced apart a distance equal to the distance between adjacent areas for cutting the substrate. With such a saw configuration, multiple parallel cuts through the substrate can be made substantially simultaneous, thus essentially increasing the speed of cutting a substrate by the number of blades utilized in tandem. Because of the small size of the individual semiconductor devices mounted and/or encapsulated on the substrate and the correspondingly small distances between adjacent cutting areas on the substrate, it may be desirable to space the blades of the saw more than one cutting area apart. For example, if the blades of a two-blade saw are spaced two cutting areas apart, a first cut would cut the first and third laterally separated cutting areas. A second pass of the blades through the substrate would cut through the second and fourth streets. The blades would then be indexed to cut through the fifth and seventh streets, then sixth and eighth, and so on.

In yet another embodiment, at least one blade of a multi-blade saw is independently raisable relative to the other blade or blades when only a single cut is desired on a particular pass of the carriage. Such a saw configuration has special utility where the blades are spaced close enough to cut in parallel on either side of larger encapsulated semiconductor devices, but use single blade capability for dicing any smaller integrated circuits. For example, a first pass of the blades of a two-blade saw could cut a first set of adjacent cutting areas of the substrate defining a column of larger semiconductor devices on the substrate. One blade could then be independently raised or elevated to effect a subsequent pass of the remaining blade cutting along a cutting area of the substrate that may be too laterally close to an adjacent street to allow both blades to cut simultaneously, or that merely defines a single column of narrower semiconductor devices. This feature would also permit parallel scribing of the surface of the substrate to mutually isolate conductors from, for example, tie bars or other common links required during fabrication, with subsequent passage by a single blade indexed to track between the scribe lines to completely sever or singulate the adjacent portions of the substrate.

In still another embodiment, at least one blade of a multi-blade saw is independently laterally translatable relative to the other blade or blades. Thus, in a two-blade saw, for example, the blades could be laterally adjusted between consecutive saw passes of the sawing operation to accommodate different widths between cutting areas of the substrate. It should be noted that this embodiment could be combined with other embodiments herein to provide a wafer saw that has blades that are both laterally translatable and independently raisable, or one translatable and one raisable, as desired.

### BRIEF DESCRIPTION OF THE DRAWINGS

FIG. 1 is a schematic side view of a first preferred embodiment of a wafer saw in accordance with the present invention;

FIG. 2 is a schematic front view of the wafer saw illustrated in FIG. 1;

FIG. 3 is a schematic front view of a second embodiment of a wafer saw in accordance with the present invention;

FIG. 4 is a schematic front view of a third embodiment of a wafer saw in accordance with the present;

FIG. 5 is a top view of an array of semiconductor devices on a substrate;

FIG. 6 is a bottom view of the array of semiconductor devices on a substrate illustrated in drawing FIG. 5;

FIG. 7 is a top view of a substrate chuck according to the present invention for the sawing of the array of semiconductor devices on a substrate illustrated in drawing FIG. 5 and drawing FIG. 6;

FIG. 8 is a side view taken along line 8-8 of drawing FIG. 7 of the substrate chuck according to the present invention;

FIG. 9 is a schematic view of a silicon semiconductor wafer having variously sized semiconductor devices therein to be diced with the saw;

FIG. 10 is a schematic view of another silicon semiconductor wafer having variously sized semiconductor devices therein to be diced with the saw;

FIG. 11 is a top view of a portion of a semiconductor substrate bearing conductive traces connected by tie bars;

FIG. 12 is a top view of a portion of a semiconductor substrate bearing three different types of components formed thereon;

FIG. 13 is a top view of an alternative substrate chuck according to the present invention for the sawing of the array of semiconductor devices on a substrate illustrated in drawing FIG. 5 and drawing FIG. 6; and

FIG. 14 is a side view taken along line 8-8 of drawing FIG. 13 of the substrate chuck according to the present invention.

### DETAILED DESCRIPTION OF THE PREFERRED EMBODIMENTS

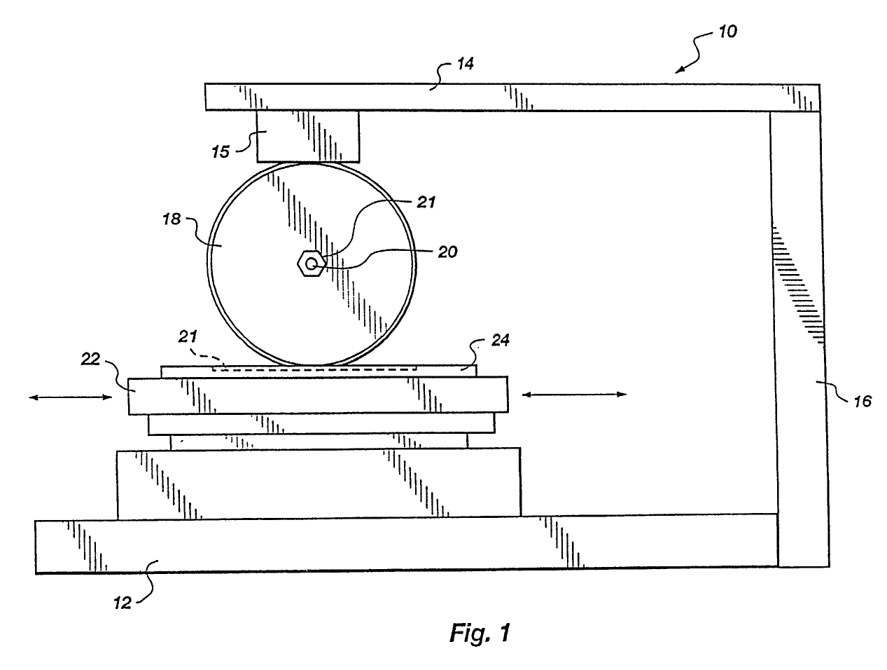

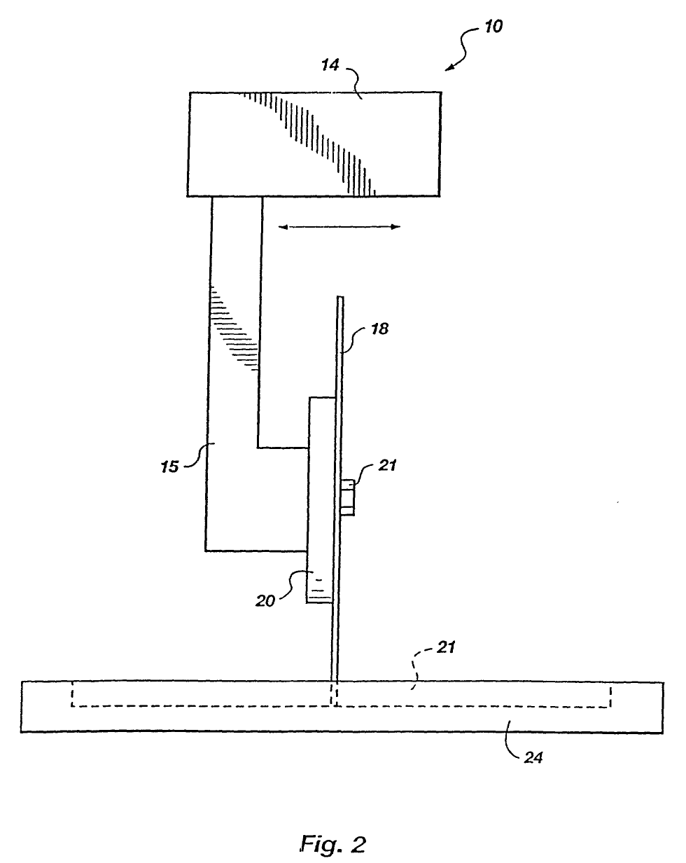

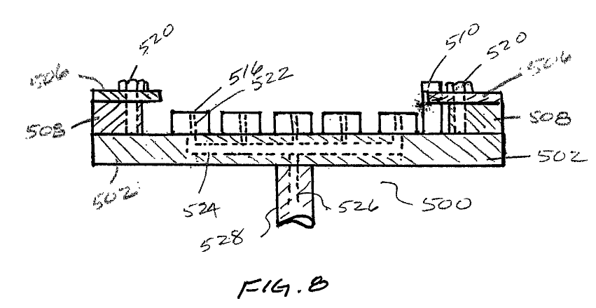

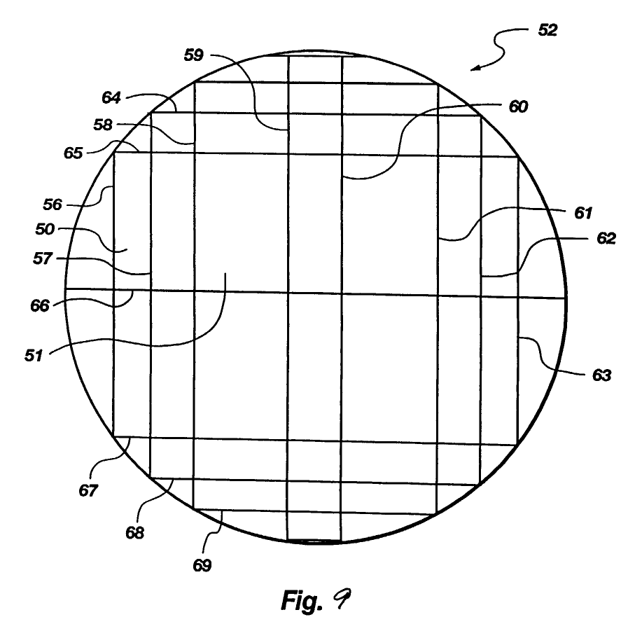

As illustrated in drawing FIGS. 1 and 2, an exemplary wafer saw 10 to be used with the present invention is comprised of a base 12 to which extension arms 14 and 15 suspended by support 16 are attached. A substrate saw blade 18 is attached to a spindle or hub 20 which is rotatably attached to the extension arm 15. The blade 18 may be secured to the hub 20 and extension arm 15 by a threaded nut 21 or other means of attachment known in the art. The substrate saw 10 also includes a translatable substrate table 22 movably attached in both X and Y directions (as indicated by arrows in drawing FIGS. 1 and 2) to the base 12. The table 22 used to hold the chuck 500 (See drawing FIGS. 7, 8, 13, and 14) of the present invention thereon by any suitable attachment apparatus. Alternatively, blade 18 may be translatable relative to the table 22 to achieve the same relative X-Y movement of the blade 18 to the table 22. A substrate 24 to be scribed or sawed may be securely mounted to the table 22. As used herein, the term “saw” includes scribing of a substrate, the resulting scribe line not completely extending through the substrate. Further, the term “substrate”, includes any suitable type substrate to which a semiconductor device may be attached, such as FR-4 board, silicon substrate, traditional full semiconductor wafers of silicon, gallium arsenide, or indium phosphide and other semiconductor materials, partial wafers, and other equivalent structures known in the art wherein a semiconductor material table or substrate is present. For example, so-called silicon-on-insulator or “SOI” structures, wherein silicon is carried on a glass, ceramic or sapphire (“SOS”) base, or other such structures as known in the art, are encompassed by the term “substrate” used herein. Likewise, “semiconductor substrate” may be used to identify wafers and other structures to be singulated into smaller elements.

The saw 10 is capable of lateral multi-indexing of the table 22 having a chuck 500 or blade 18 or, in other words, translatable from side-to-side in drawing FIG. 2 and into and out of the plane of the page in drawing FIG. 1, various non-uniform distances. As noted before, such non-uniform distances may be mere multiples of a unit distance, or may comprise unrelated varying distances, as desired. Accordingly, a substrate 24 having variously sized integrated circuits or other devices or components therein may be sectioned or diced into its non-uniformly sized components by the multi-indexing saw 10. In addition, as previously alluded, the saw 10 may be used to create scribe lines or cuts that do not extend through the substrate 24. The substrate 24 can then subsequently be diced by other methods known in the art or sawed completely through after the blade 18 has been lowered to traverse the substrate to its full depth or thickness.

Before proceeding further, it will be understood and appreciated that design and fabrication of a substrate saw for use with the present invention having the previously-referenced, multi-indexing capabilities, independent lateral blade translation and independent blade raising or elevation is within the ability of one of ordinary skill in the art, and that likewise the control of such a device to effect the multiple-indexing (whether in units of fixed increments or otherwise), lateral blade translation and blade elevation may be effected by suitable programming of the software-controlled operating system, as known in the art. Accordingly, no further description of hardware components or of a control system to effectuate operation of the apparatus of the invention is necessary

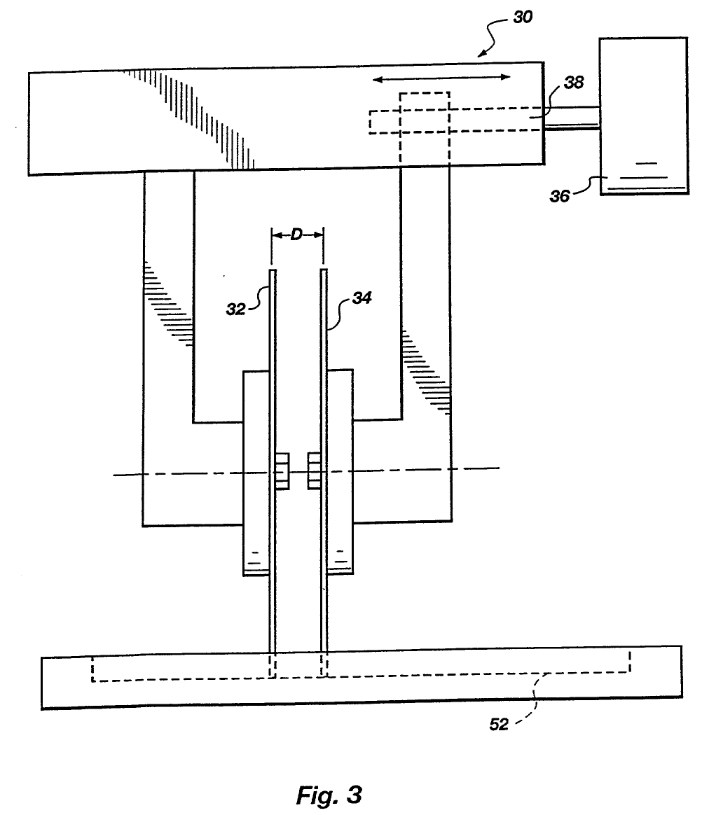

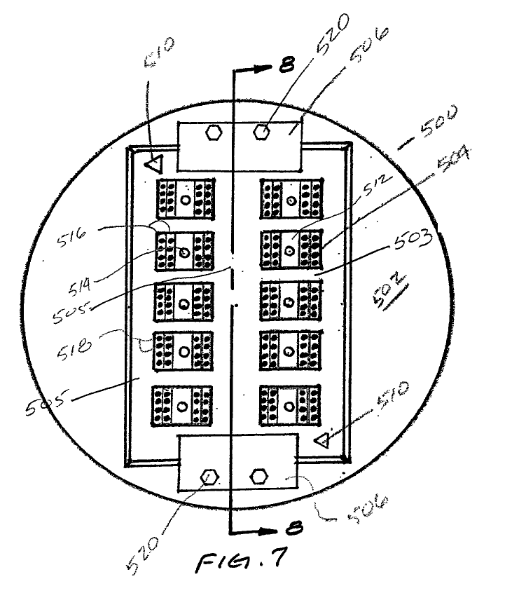

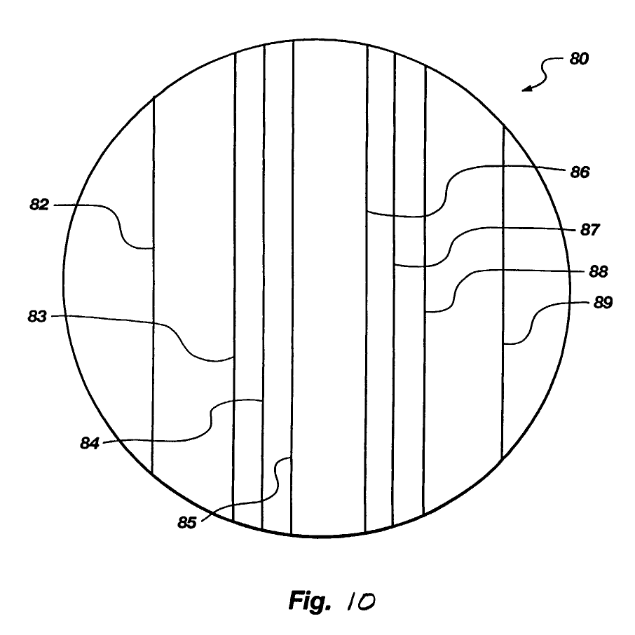

Referring now to drawing FIG. 3, another illustrated embodiment of a substrate saw 30 is shown having two laterally-spaced blades 32 and 34 with their centers of rotation “C” in substantial parallel alignment transverse to the planes of the blades. For a rectangular substrate or a conventional substantially circular silicon semiconductor wafer each having a plurality of similarly configured semiconductor devices 42 or integrated circuits 42 arranged in evenly spaced rows and columns, the blades can be spaced a distance “D” substantially equal to the distance between adjacent areas 44 streets 44 defining the space between each integrated circuit 42. In addition, if the areas 44 of a substrate 40 or streets 44 of wafer 40 are too closely spaced for side-by-side blades 32 and 34 to cut along adjacent streets, the blades 32 and 34 can be spaced a distance “D” substantially equal to the distance between two or more areas or streets. For example, a first pass of the blades 32 and 34 could cut along streets 44a and 44c and a second pass along streets 44b and 44d. The blades could then be indexed to cut the next series of areas or streets and the process repeated as desired number of times. If, however, the semiconductor devices 42 of a substrate 40 or integrated circuits 42 of a wafer 52 have various sizes, such as integrated circuits 50 and 51 as illustrated in drawing FIG. 9, at least one blade 34 is laterally translatable relative to the other blade 32 to cut along the areas or streets, such as street 56, separating the variously sized integrated circuits 50. The blade 34 may be variously translatable by a stepper motor 36 having a lead screw 38 or by other devices known in the art, such as high precision gearing in combination with an electric motor or hydraulics, or other suitable mechanical drive and control assemblies. For a substrate 40 or wafer 52, the integrated circuits, such as integrated circuits 50 and 51, may be diced by setting the blades 32 and 34 to simultaneously cut along areas 58 or 59 (See drawing FIG. 6.) streets 56 and 57, indexing the blades, setting them to a wider lateral spread and cutting along areas 56 or 57 or streets 58 and 59, indexing the blades while monitoring the same lateral spread or separation and cutting along streets 60 and 61, and then narrowing the blade spacing and indexing the blades and cutting along other areas (not shown) and streets 62 and 63. The substrate 40 or wafer 52 could then be rotated 90° and the blade separation and indexing process repeated for areas 58 or 59 or vice versa (See drawing FIG. 6.) and streets 64 and 65, streets 66 and 67, and streets 68 and 69.

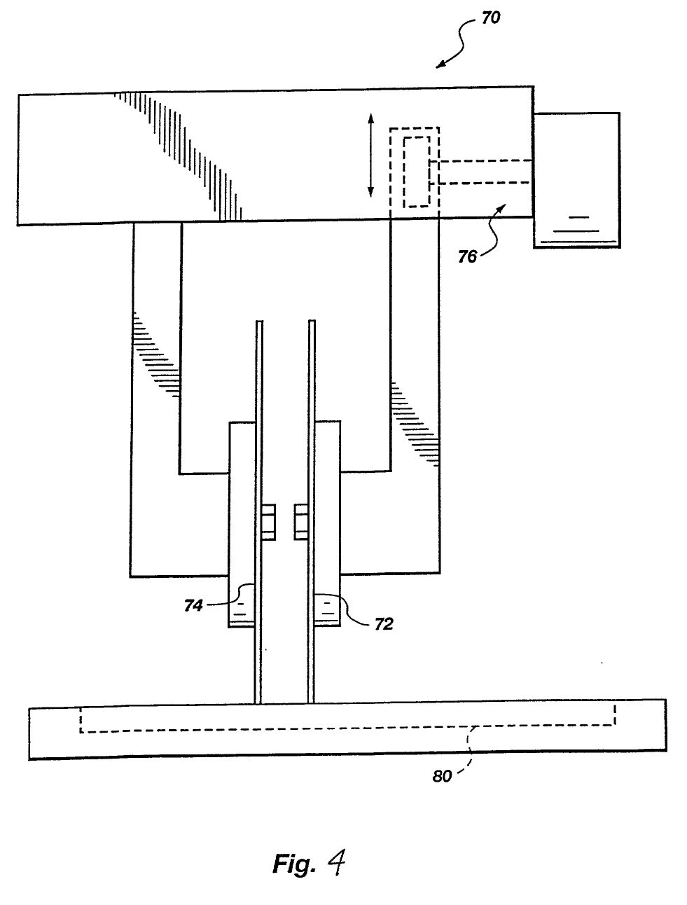

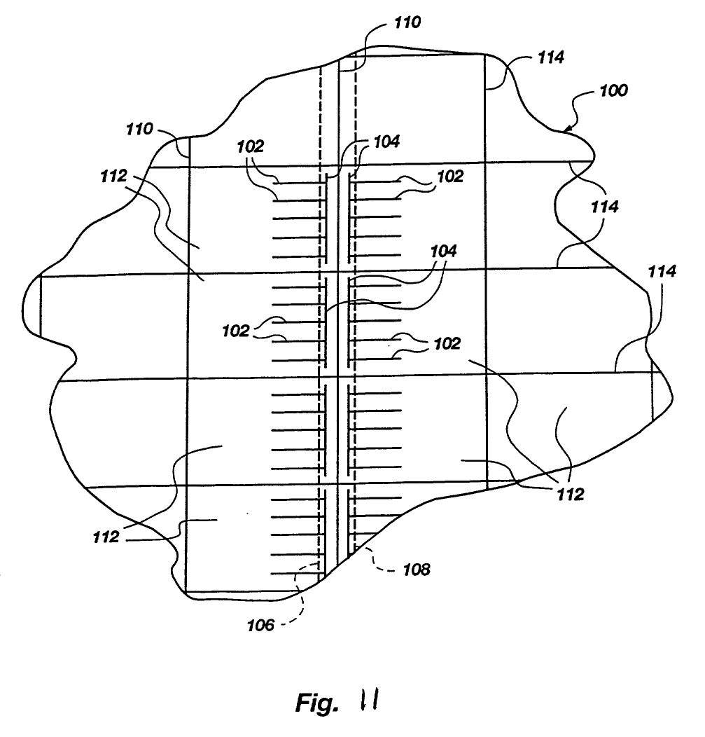

As illustrated in drawing FIG. 4, a wafer saw 70 according to the present invention is shown having two blades 72 and 74, one of which is independently raisable (as indicated by an arrow) relative to the other. As used herein, the term “raisable” includes vertical translation either up or down. Such a configuration may be beneficial for situations where the distance between adjacent cutting areas of a substrate and/or streets of a wafer is less than the minimum lateral achievable distance between blades 72 and 74, or only a single column of narrow semiconductor devices or semiconductor dice is to be cut, such as at the edge of a substrate or wafer. Thus, when cutting a wafer 80, as better illustrated in drawing FIG. 10 depicting a wafer, the two blades 72 and 74 can make a first pass along streets 82 and 83. One blade 72 can then be raised, the wafer 80 indexed relative to the unraised blade 74 and a second pass performed along street 84 only. Blade 72 can then be lowered and the wafer 80 indexed for cutting along streets 85 and 86. The process can be repeated for streets 87 (single-blade pass), 88, and 89 (double-blade pass). The elevation mechanism 76 for blade 72 may comprise a stepper motor, a precision-geared hydraulic or electric mechanism, a pivotable arm which is electrically, hydraulically or pneumatically powered, or other means well known in the art.

Finally, it may be desirable to combine the lateral translation feature of the embodiment of the wafer saw 30 illustrated in drawing FIG. 3 with the independent blade raising feature of the wafer saw 70 of drawing FIG. 6. Such a wafer saw could use a single blade to cut along areas or streets that are too closely spaced for dual-blade cutting or in other suitable situations, and use both blades to cut along variously spaced areas or streets where the lateral distance between adjacent cutting areas or streets is sufficient for both blades to be engaged.

It will be appreciated by those skilled in the art that the embodiments herein described while illustrating certain embodiments are not intended to so limit the invention or the scope of the appended claims. More specifically, this invention, while being described with reference to substrates for semiconductor devices thereon, either encapsulated or not, semiconductor wafers containing integrated circuits or other semiconductor devices, has equal utility to any type of substrate to be scribed or singulated. For example, fabrication of test inserts or chip carriers formed from a silicon (or other semiconductor substrate) or wafer and used to make temporary or permanent chip-to-wafer, chip-to-chip, and chip-to-carrier interconnections and that are cut into individual or groups of inserts, as described in U.S. Pat. Nos. 5,326,428 and 4,937,653, may benefit from the multi-indexing method and apparatus described herein.

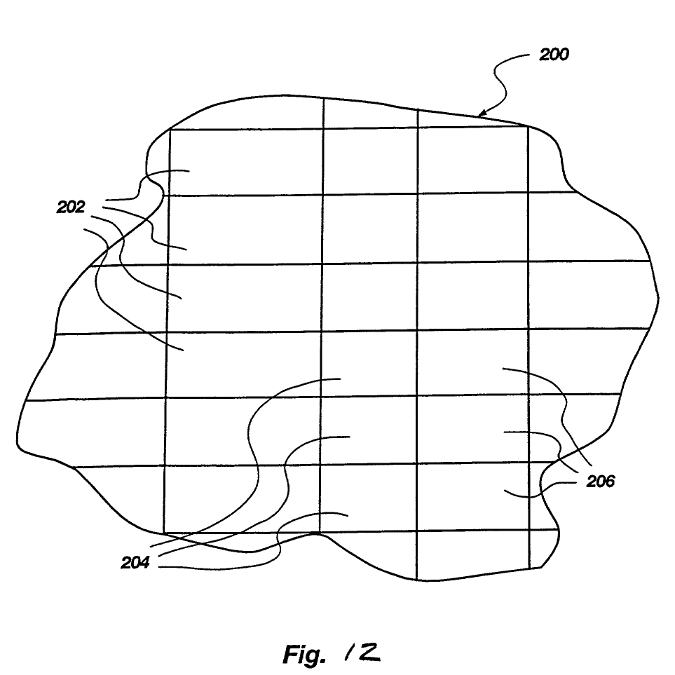

For example, illustrated in drawing FIG. 11, a semiconductor substrate 100 may have traces 102 formed thereon by electrodeposition techniques required connection of a plurality of traces 102 through a tie bar 104. A two-blade saw in accordance with the present invention may be employed to simultaneously scribe substrate 100 along parallel lines 106 and 108 flanking a street 110 in order to sever tie bars 104 of adjacent substrate segments 112 from their associated traces 102. Following such severance, the two columns of adjacent substrate segments 112 (corresponding to what would be termed “dice” integrated circuits were formed thereon) are completely severed along street 110 after the two-blade saw is indexed for alignment of one blade therewith, and the other blade raised out of contact with substrate 100. Subsequently, when either the saw or the substrate carrier is rotated 90°, singulation of the segments 112 is completed along mutually parallel streets 114. Thus, substrate segments 112 for test or packaging purposes may be fabricated more efficiently in the same manner as dice and in the sizes and shapes.

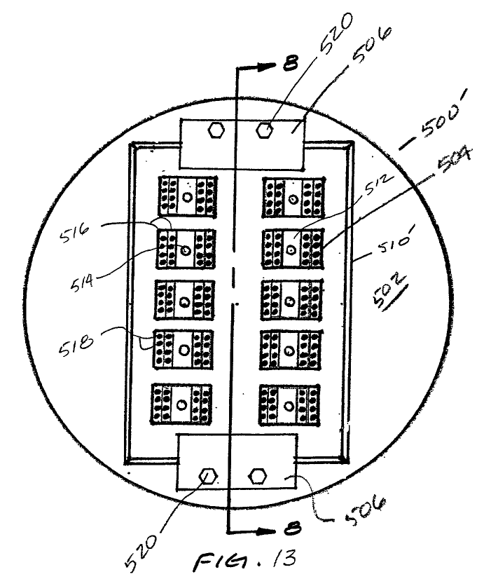

As shown in drawing FIG. 12, a portion of a substrate 200 is depicted with three adjacent columns of varying-width segments, the three widths of segments illustrating batteries 202, chips 204 and antennas 206 of a semiconductor device, such as an RFID device. With all of the RFID components formed on a single substrate 200, an RFID module may be assembled by a single pick-and-place apparatus at a single work station. Thus, complete modules may be assembled without transfer of partially-assembled modules from one station to the next to add components. Of course, this approach may be employed to any module assembly wherein all of the components are capable of being fabricated on a single semiconductor substrate. Fabrication of different components by semiconductor device fabrication techniques known in the art is within the ability of those of ordinary skill in the art, and therefore no detailed explanation of the fabrication process leading to the presence of different components on a common wafer or other substrate is necessary. Masking of semiconductor device elements not involved in a particular process step is widely practiced, and so similar isolation of entire components is also easily effected to protect the elements of a component until the next process step with which it is involved.

Further, the saw used with the present invention has particular applicability to the fabrication of custom or non-standard integrated circuits or other components, wherein a capability for rapid and easy die size and shape adjustment on a substrate-by-substrate or wafer-by-wafer basis is highly beneficial and cost-effective. In the present saw it may be desirable to have at least one blade of the independently laterally translatable blade configuration be independently raisable relative to the other blade or blades, or a single blade may be both translatable and raisable relative to one or more other blades and to the target substrate or wafer. In addition, while for purposes of simplicity, some of the preferred embodiments of the substrate saw are illustrated as having two blades, however, the saw may have more or less than two blades.

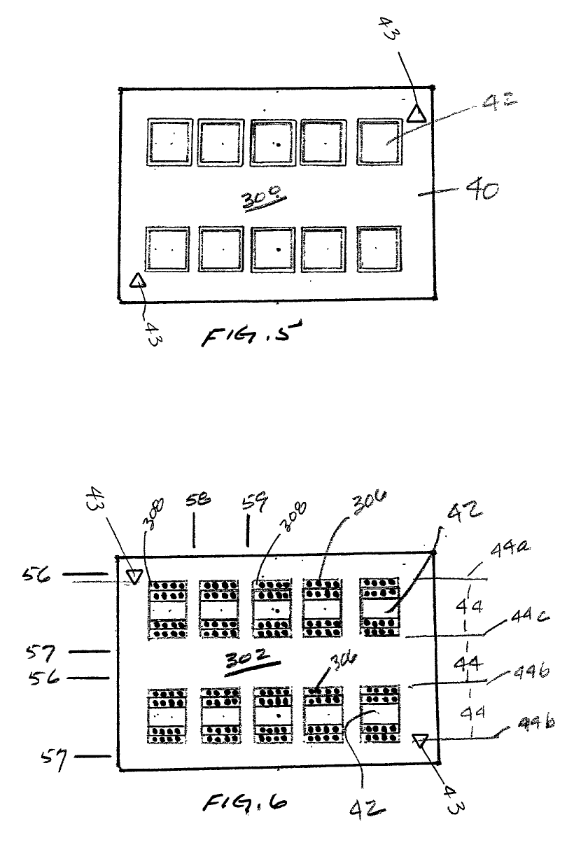

Referring to drawing FIG. 5, a first side 300 of a substrate 40 is illustrated having a plurality of semiconductor devices 42 located thereon. each semiconductor device 42 having been previously encapsulated in a suitable molding process. The substrate 40 may be of any suitable material, such as described herein.

Referring to drawing FIG. 6, another side 302 of the substrate 40 is illustrated having the plurality of semiconductor devices 42 connected to a plurality of solder balls or suitable type connectors 306 through suitable circuits (not shown) on substrate 40 and from the encapsulated semiconductor devices 42. The substrate 40 may contain circuits thereon, such as illustrated in drawing FIG. 11.

Referring to drawing FIG. 7, illustrated in a top view is a dicing chuck 500 suitable for use with the table 22 of the substrate saw 10 and the substrate 40 illustrated in drawing FIGS. 5 and 6. The chuck 500 comprises a chuck table 502 having a shaft 528 attached thereto for mounting on the table 22 using suitable apparatus, a plurality of cutting pedestals 504 having the desired spacing to mate with the semiconductor devices 42 of substrate 40 and connectors 306 os side 302 of substrate 42, a pair of clamps 506 mounted on clamp pedestals 508 (see drawing FIG. 8), and one or more alignment pins 510, if desired, for aligning the substrate 40 on the chuck 500. Each cutting pedestal 504 includes a portion 512 having an aperture 514 therein for mating with the portion of the semiconductor device 42 on side 302 thereof and portions 516 having a plurality of recessed areas 518 therein for mating with the connectors 306 in areas 308 of side 302 of substrate 40. The aperture 514 in the cutting pedestal 504 may be connected to a source of vacuum (not shown) to help retain the semiconductor devices 42 on the cutting pedestal 504. The shape, size and spacing of the recessed areas 518 on each cutting pedestal 504 will vary with the type, size, and spacing of the connectors 306 of side 302 of substrate 40. The clamps 506 mounted on clamp pedestals 508 may be secured thereto by any suitable type of retaining apparatus, such as a threaded member 520. The chuck 500 may be fabricated from any suitable material, such as metal, common used for the dicing of substrates having semiconductor devices thereon.

Referring to drawing FIG. 8, the chuck 500 illustrated in a side view. As shown, the apertures 516 in each cutting pedestal 504 has an aperture 522 connected to aperture 524 which, in turn, is connected to aperture 526 in the chuck shaft 526 to supply vacuum from a source of vacuum to each cutting pedestal 504. The shape, size, configuration, and layout of the apertures 522, 524, and 526 may be any suitable desired configuration to supply vacuum to each cutting pedestal 504. The alignment pins 510 mate with alignment apertures 43 in the substrate 40 (See drawing FIGS. 5 and 6.). The alignment pins 510 may be any desired configuration, size, and shape to mate with any alignment aperture in substrate 40. The threaded fasteners 520 may be any suitable type to retain the substrate clamps 506 on the clamp pedestals 508. The substrate clamps 506 may be of any suitable shape, size, and configuration to mate with portions of the substrate 40 to retain portions thereof on the cutting pedestals 504 and, if desired, on clamp pedestal 508.

Each of the cutting pedestals 504 is spaced from an adjacent cutting pedestal 504 by a space 503 and space 505 which also extends both between the cutting pedestals 504 and one the exterior of the cutting pedestals 504 to allow a saw blade 18 of a saw as described herein to cut a substrate 40 into the desired number of singulated semiconductor devices 42, each singulated semiconductor device 42 having a plurality of connectors 306 attached to one side thereof. In this manner, an array of any desired number of semiconductor devices 42 on a substrate 40 may be retained in the chuck 500 to be singulated by a saw 10 having one or more blades 18. Additionally, since the depth and width of a saw 10 may vary, any spacing of the semiconductor devices 42 on the substrate 40 may be used.

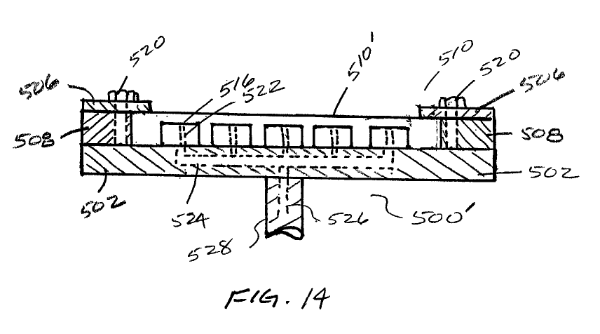

Referring to drawing FIGS. 13 and 14, an alternative chuck 500′ according to the present invention is illustrated. In the alternative chuck 500′ of the present invention, the alignment pins 510 have been eliminated. The chuck table 502 includes a recess 510′ therein having the size, configuration, and shape to mate and align a substrate 40 within the recess 510′ prior to being retained therein by the clamps 506 on clamp pedestals 508. In this manner, a substrate 40 may be located by the perimeter of the recess 510′ on the cutting pedestals 504 being retained thereon by a vacuum supplied through aperture 514 and clamps 506. Except for the elimination of the alignment pins 510 and the addition of an alignment recess 510′ in the table 502 of the chuck 500′, the chuck 500′ is the same as the chuck 500 illustrated in drawing FIG. 7 and drawing FIG. 8.

The chuck 500 and 500′ of the present invention may include alterations and features, changes, additions, and deletions which are intended to be within the scope of the invention. For instance, the chuck may be of any size, shape, and configuration. The chuck may have any desired number of cutting pedestals of any size, shape, and configuration thereon, may have any desired number, shape, size, and configuration of clamps and clamp pedestals, may have any desired alignment apparatus for a substrate thereon, etc.

Thus, while certain representative embodiments and details have been shown for purposes of illustrating the invention, it will be apparent to those skilled in the art that various changes in the invention disclosed herein may be made without departing from the scope of the invention, which is defined in the appended claims.

What is claimed is:

1. In combination, a semiconductor substrate singulation saw and a chuck for holding a substrate comprising:
a saw having at least one blade supported above a table and oriented to cut mutually parallel paths in the surface of a semiconductor substrate positioned on said table; and
a chuck having at least one cutting pedestal located thereon mounted on said table, said chuck for holding said substrate during the cutting thereof by said saw.

2. The combination of claim 1, wherein said chuck further comprises:
a chuck table; and
a plurality of cutting pedestals, each cutting pedestal being mounted on said chuck table.

3. The combination of claim 2, wherein said chuck further comprises:
at least one clamp pedestal; and
at least one substrate clamp removable attached to a portion of the at least one clamp pedestal.

4. The combination of claim 3, wherein said chuck further comprises:
at least one alignment apparatus having a portion attached to the chuck table.

5. The combination of claim 4, wherein said alignment apparatus comprises:
at least one alignment pin having a portion for engaging a portion of a substrate.

6. The combination of claim 4, wherein said alignment apparatus comprises:
an aperture in the chuck table for receiving said substrate therein.

7. The combination of claim 4, wherein said alignment apparatus comprises:
a pair of alignment pins, each alignment pin having a portion thereof attached to the chuck table and a portion for engaging a portion of said substrate.

8. The combination of claim 1, the saw further comprising:
at least two blades for sawing said substrate.

9. The combination of claim 8, wherein at least one of said at least two blades is laterally translatable relative to another of said at least two blades.

10. The combination of claim 9, wherein at least one of said at least two blades is raisable relative to another of said at least two blades.

11. The combination of claim 8, wherein said table is translatable in at least one direction relative to said at least two blades.

12. The combination of claim 8, wherein said at least two blades are translatable in at least one direction relative to said table.

13. In combination, a semiconductor substrate singulation saw and a table for mounting a substrate comprising:
a saw having at least two blades supported above a table and oriented to cut mutually parallel paths in the surface of a semiconductor substrate positioned on said table; and
a chuck having at least one cutting pedestal located thereon mounted on said table, said chuck for holding said substrate during the cutting thereof by said saw.

14. The combination of claim 13, wherein said chuck further comprises:
a chuck table; and
a plurality of cutting pedestals, each cutting pedestal being mounted on said chuck table.

15. The combination of claim 14, wherein said chuck further comprises:
at least one clamp pedestal; and
at least one substrate clamp removable attached to a portion of the at least one clamp pedestal.

16. The combination of claim 15, wherein said chuck further comprises:
at least one alignment apparatus having a portion attached to the chuck table.

17. The combination of claim 16, wherein said alignment apparatus comprises:
at least one alignment pin having a portion for engaging a portion of a substrate.

18. The combination of claim 16, wherein said alignment apparatus comprises:
an aperture in the chuck table for receiving said substrate therein.

19. The combination of claim 16, wherein said alignment apparatus comprises:
a pair of alignment pins, each alignment pin having a portion thereof attached to the chuck table and a portion for engaging a portion of said substrate.

20. The combination of claim 13, the saw further comprising:
at least two blades for sawing said substrate.

21. The combination of claim 20, wherein at least one of said at least two blades is laterally translatable relative to another of said at least two blades.

22. The combination of claim 21, wherein at least one of said at least two blades is raisable relative to another of said at least two blades.

23. The combination of claim 20, wherein said table is translatable in at least one direction relative to said at least two blades.

24. The combination of claim 20, wherein said at least two blades are translatable in at least one direction relative to said table.

25. A chuck used for semiconductor substrate singulation for holding a substrate to be singulated in a saw having a table comprising:
a chuck having at least one cutting pedestal located thereon mounted on said table, said chuck for holding said substrate during the cutting thereof by said saw.

26. The chuck of claim 25, wherein said chuck further comprises:
a plurality of cutting pedestals, each cutting pedestal being mounted on said chuck table.

27. The chuck of claim 26, wherein said chuck further comprises:
at least one clamp pedestal; and
at least one substrate clamp removable attached to a portion of the at least one clamp pedestal.

28. The chuck of claim 27, wherein said chuck further comprises:
at least one alignment apparatus having a portion attached to the chuck table.

29. The chuck of claim 28, wherein said alignment apparatus comprises:
at least one alignment pin having a portion for engaging a portion of a substrate.

30. The chuck of claim 28, wherein said alignment apparatus comprises:
an aperture in the chuck table for receiving said substrate therein.

31. The chuck of claim 28, wherein said alignment apparatus comprises:
a pair of alignment pins, each alignment pin having a portion thereof attached to the chuck table and a portion for engaging a portion of said substrate.

32. A method for singulating a plurality of semiconductor devices located on a substrate comprising:
providing a saw having at least one blade and a table;
providing a chuck having at least one cutting pedestal located thereon mounted on the table, said chuck for holding said substrate during the cutting thereof by said saw;
providing a substrate having a plurality of semiconductor devices located thereon;
placing said substrate in the chuck;
aligning the substrate in the chuck;
supporting at least one semiconductor device on a portion of the chuck; and
sawing at least one semiconductor device from said substrate.

33. The method of claim 32, further comprising:
applying a vacuum to a portion of the at least one semiconductor device supported on a portion of the at least one cutting pedestal of the chuck.

34. The method of claim 32, further comprising:
sawing a plurality of semiconductor devices from said substrate at substantially the same time.

35. The method of claim 32, further comprising:
supporting a plurality of semiconductor devices on a portion of the chuck.

36. The method of claim 34, further comprising:
supporting a plurality of semiconductor devices on portions of the chuck during the sawing thereof from said substrate.

37. A method for singulating a plurality of semiconductor devices located on a substrate comprising:
providing a saw having at least two blades and a table;
providing a chuck having at least two cutting pedestals located thereon mounted on the table, said chuck for holding said substrate during the cutting thereof by said saw;
providing a substrate having a plurality of semiconductor devices located thereon;
placing said substrate in the chuck;
aligning the substrate in the chuck;
supporting at least two semiconductor devices on portions of the chuck; and
sawing at least two semiconductor devices from said substrate.

38. The method of claim 37, further comprising:
applying a vacuum to a portion of the at least two semiconductor devices supported on portions of the at least one cutting pedestal of the chuck.

39. The method of claim 37, further comprising:
sawing more than two semiconductor devices from said substrate at substantially the same time.

40. The method of claim 37, further comprising:
supporting more than two semiconductor devices on a portion of the chuck.

41. The method of claim 37, further comprising:
supporting a plurality of more than two semiconductor devices on portions of the chuck during the sawing thereof from said substrate.

42. An apparatus for singulation of a semiconductor substrate comprising:
a saw having at least one blade supported above a table and oriented to cut mutually parallel paths in the surface of a semiconductor substrate positioned on said table; and
a chuck having at least one cutting pedestal located thereon mounted on said table, said chuck for holding said substrate during the cutting thereof by said saw.

43. The apparatus of claim 42, wherein said chuck further comprises:
a chuck table; and
a plurality of cutting pedestals, each cutting pedestal being mounted on said chuck table.

44. The apparatus of claim 42, wherein said chuck further comprises:
at least one clamp pedestal; and
at least one substrate clamp removable attached to a portion of the at least one clamp pedestal.

45. The apparatus of claim 44, wherein said chuck further comprises:
at least one alignment apparatus having a portion attached to the chuck table.

46. The apparatus of claim 45, wherein said alignment apparatus comprises:
at least one alignment pin having a portion for engaging a portion of a substrate.

47. The apparatus of claim 45, wherein said alignment apparatus comprises:
an aperture in the chuck table for receiving said substrate therein.

48. The apparatus of claim 45, wherein said alignment apparatus comprises:
a pair of alignment pins, each alignment pin having a portion thereof attached to the chuck table and a portion for engaging a portion of said substrate.

49. The apparatus of claim 42, the saw further comprising:
at least two blades for sawing said substrate.

50. The apparatus of claim 49, wherein at least one of said at least two blades is laterally translatable relative to another of said at least two blades.

51. The apparatus of claim 50, wherein at least one of said at least two blades is raisable relative to another of said at least two blades.

52. The apparatus of claim 49, wherein said table is translatable in at least one direction relative to said at least two blades.

53. The apparatus of claim 49, wherein said at least two blades are translatable in at least one direction relative to said table.

54. An apparatus for the singulation of a substrate comprising:
a saw having at least two blades supported above a table and oriented to cut mutually parallel paths in the surface of a semiconductor substrate positioned on said table; and
a chuck having at least one cutting pedestal located thereon mounted on said table, said chuck for holding said substrate during the cutting thereof by said saw.

55. The apparatus of claim 54, wherein said chuck further comprises:
a chuck table; and
a plurality of cutting pedestals, each cutting pedestal being mounted on said chuck table.

56. The apparatus of claim 55, wherein said chuck further comprises:
at least one clamp pedestal; and
at least one substrate clamp removable attached to a portion of the at least one clamp pedestal.

57. The apparatus of claim 56, wherein said chuck further comprises:
at least one alignment apparatus having a portion attached to the chuck table.

58. The apparatus of claim 57, wherein said alignment apparatus comprises:
at least one alignment pin having a portion for engaging a portion of a substrate.

59. The apparatus of claim 57, wherein said alignment apparatus comprises:
an aperture in the chuck table for receiving said substrate therein.

60. The apparatus of claim 57, wherein said alignment apparatus comprises:
a pair of alignment pins, each alignment pin having a portion thereof attached to the chuck table and a portion for engaging a portion of said substrate.

61. The apparatus of claim 54, the saw further comprising:
at least two blades for sawing said substrate.

62. The apparatus of claim 61, wherein at least one of said at least two blades is laterally translatable relative to another of said at least two blades.

63. The apparatus of claim 62, wherein at least one of said at least two blades is raisable relative to another of said at least two blades.

64. The apparatus of claim 61, wherein said table is translatable in at least one direction relative to said at least two blades.

65. The apparatus of claim 61, wherein said at least two blades are translatable in at least one direction relative to said table.

66. A method for singulating a substrate having a plurality of semiconductor devices located thereon using a saw having at least one blade and a table having a chuck having at least one cutting pedestal, said chuck for holding said substrate, comprising:
placing said substrate in the chuck;
aligning the substrate in the chuck;
supporting at least one semiconductor device on a portion of the chuck; and
sawing at least one semiconductor device from said substrate.

67. The method of claim 66, further comprising:
applying a vacuum to a portion of the at least one semiconductor device supported on a portion of the at least one cutting pedestal of the chuck.

68. The method of claim 66, further comprising:
sawing a plurality of semiconductor devices from said substrate at substantially the same time.

69. The method of claim 66, further comprising:
supporting a plurality of semiconductor devices on a portion of the chuck.

70. The method of claim 68, further comprising:
supporting a plurality of semiconductor devices on portions of the chuck during the sawing thereof from said substrate.

71. A method for singulating a substrate having plurality of semiconductor devices using a saw having at least two blades and a table having a chuck having at least two cutting pedestals, said chuck for holding said substrate, comprising:
placing said substrate in the chuck;
aligning the substrate in the chuck;
supporting at least two semiconductor devices on portions of the chuck; and
sawing at least two semiconductor devices from said substrate.

72. The method of claim 71, further comprising:
applying a vacuum to a portion of the at least two semiconductor devices supported on portions of the at least one cutting pedestal of the chuck.

73. The method of claim 71, further comprising:
sawing more than two semiconductor devices from said substrate at substantially the same time.

74. The method of claim 71, further comprising:
supporting more than two semiconductor devices on a portion of the chuck.

75. The method of claim 71, further comprising:
supporting a plurality of more than two semiconductor devices on portions of the chuck during the sawing thereof from said substrate.
